(19) United States
(12) Patent Application Publication
(10) Pub. No.: US 2026/0211056 A1
(43) Pub. Date: Jul. 23, 2026

(54) METHOD OF MEASURING LITHIUM PLATING IN LITHIUM-ION BATTERIES

(71) Applicant: The Hong Kong University of Science and Technology, Hong Kong (CN)

(72) Inventors: FAN SHI, Hong Kong (CN); WUKE XU, Hong Kong (CN)

(73) Assignee: The Hong Kong University of Science and Technology, Hong Kong (CN)

(21) Appl. No.: 19/426,187

(22) Filed: Dec. 19, 2025

Related U.S. Application Data
(60) Provisional application No. 63/747,905, filed on Jan. 22, 2025.

(51) Int. Cl. G01R 31/392; H01M 10/0525; H02J 7/84

(52) U.S. Cl. CPC G01R 31/392; H02J 7/84; H01M 10/0525

(57) ABSTRACT

Lithium plating in a lithium-ion battery is measured as a decrease in resonance frequency amplitude observed during the charging process of the lithium-ion battery. An ultrasonic transmitter is attached to one side of the lithium-ion battery and an ultrasonic receiver is attached to an opposite side of the lithium-ion battery. The lithium-ion battery is charged and, during the charging thereof, a resonance frequency ultrasonic signal is transmitted through the battery using the ultrasonic transmitter, and the signal is received by the ultrasonic receiver. The amplitude of the received resonance frequency ultrasonic signal is measured and compared against a known baseline amplitude associated with the lithium-ion battery to calculate a percentage decrease from the known baseline amplitude. The percentage decrease is output to the user. The percentage decrease corresponds to the degree of lithium plating in the lithium-ion battery and represents a quantifiable measure of the degree of lithium plating.

### CROSS-REFERENCE TO RELATED APPLICATIONS

This application claims the benefit of U.S. Provisional Patent Application No. 63/747,905, filed on Jan. 22, 2025.

### BACKGROUND

### Field

The disclosure of the present patent application relates to measuring and testing of batteries, and particularly to an ultrasonic method of measuring lithium plating in lithium-ion batteries.

### Description of Related Art

Lithium-ion batteries (LIBs) have found widespread applications across various industrial sectors due to their high energy density, efficiency and versatility. However, LIBs are susceptible to issues that can lead to rapid degradation and even failure. Among the various battery degradation mechanisms, lithium (Li) plating is one of the most critical types and has received significant concerns. During the operational cycles of LIBs, Li plating occurs when lithium ions, originally deintercalated from the cathode, encounter difficulties in intercalating into the anode. This results in the formation of a layer of metallic lithium on the surface of the anode particles. The presence of this lithium layer impedes the further intercalation of lithium ions and can lead to adverse chemical reactions with the electrolyte, including gas production and other detrimental side reactions. In extreme cases, when the thickness of the lithium layer exceeds a critical threshold, it can puncture the separator, causing a short circuit and triggering a potentially catastrophic thermal runaway event. Therefore, accurate detection and characterization of Li plating, particularly at its early stage before it begins to affect cell performance, is crucial for ensuring the safety and extending the longevity of LIBs. However, it is very challenging to detect this weak degradation due to the subtle nature of early stage Li plating.

Various methods have been employed to detect Li plating, including electrochemical techniques and physical characterization means. Electrochemical measurement approaches, such as monitoring voltage relaxation, Coulombic efficiency (CE), and electrochemical impedance spectroscopy (EIS), are considered effective for Li plating detection due to their high detection sensitivity. However, the accuracy of CE measurement can be compromised since multiple factors may lead to the same detection result apart from Li plating, causing misjudgments of the detection outcomes.

The voltage relaxation method requires a slow discharge rate and is affected by abnormal exothermic peaks. The EIS method requires complicated computation and will potentially impact the cell performance after measurements. Further, physical characterization methods, such as optical microscopy, scanning electron microscopy (SEM), and X-ray Photoelectron Spectroscopy (XPS), are commonly utilized to investigate the surface morphology of deposited Li and Li dendrites in laboratory settings, thanks to their high resolution. Nevertheless, these methods have inherent limitations, including the requirement for vacuum conditions and the risk of surface contamination in SEM and XPS. Additionally, optical observation necessitates modifications to the cell design for in-site detection. Most of these methods are demanding in terms of the size of the detection object and require expensive equipment. Other approaches, such as measuring volume changes or utilizing isothermal microcalorimetry, also have limitations, as the indices used to represent Li plating are susceptible to interference from various factors, making it challenging to identify Li plating in commercial LIBs with a complex structure.

In recent years, ultrasound-based methods for detecting and monitoring LIB performance have garnered increasing attention. Ultrasound is non-invasive and the signal shows high sensitivity to diverse defect types and affords the convenience of in situ application, making it a promising tool for enhancing battery safety. For example, ultrasonic time-of-flight (ToF) changes have been used to monitor the overall temperature variations in batteries and implemented state-of-charge (SOC) corrections during high-current charge and discharge cycles. Further, measured amplitude changes have been used to effectively detect gas generation and electrolyte dry-out within batteries. An in situ subsurface ultrasonic array imaging technique for identification, localization, and analysis of gas bubbles generated within commercial LIBs has also been developed.

In addition to the above, the use of ToF changes in ultrasonic waves to successfully detect moderate to severe Li plating in pouch cells has been used. A spatially resolved operando scanning approach to detect local Li plating under varying charging rates has also been used. The above techniques primarily detect severe Li plating and they are often accompanied by gas generation, which causes significant changes in ultrasonic signals. Most studies conduct ultrasonic experiments at frequencies around 2.25 MHz or lower. Within this particular frequency range, interlayer reflections within the battery exhibit relatively low intensity, and the resulting transmission signals mainly reveal the homogenized properties of the battery. However, this raises concerns regarding the potential underestimation of minor defect-related nuances, particularly those associated with the initial stages of mild Li plating, in the ultrasonic data.

The operation of a battery is inherently a dynamic process, during which issues like Li plating simultaneously arise. Whether it can be accurately identified and distinguished from normal operating variations in ultrasonic signals remains to be studied. These variations, such as SOC changes, can significantly affect ultrasonic signals and mask features caused by subtle early-stage Li plating. Additionally, recognizing the complexity of LIBs as intricate, multi-layered entities with quasi-periodic structures is crucial, as this layered structure induces pronounced bandgap effects, adding difficulties in understanding the underlying physical mechanisms of ultrasonic signal changes associated with Li plating. However, these effects can also be leveraged to enhance detection sensitivity. In-phase resonant frequencies within batteries have been identified, owing to their quasi-periodic layered structure, and these in-phase resonant frequencies have been utilized to assess SOC and the uniformity of interlayer structures. Ultrasonic responses across a range of frequencies still need to be explored in order to comprehensively analyze the ultrasonic frequency spectrum of batteries and pinpoint the most sensitive frequency range for detecting Li plating.

Thus, a method of measuring lithium plating in lithium-ion batteries solving the aforementioned problems is desired.

### SUMMARY

Lithium (Li) plating in a lithium-ion battery is measured as a decrease in resonance frequency amplitude observed during the charging process of the lithium-ion battery. An ultrasonic transmitter is attached to one side of the lithium-ion battery and an ultrasonic receiver is attached to an opposite side of the lithium-ion battery. As a non-limiting example, each of the ultrasonic transmitter and the ultrasonic receiver may be a piezoelectric transducer (PZT). The lithium-ion battery is charged and, during the electrical charging thereof, a resonance frequency ultrasonic signal is transmitted through the battery using the ultrasonic transmitter, and the signal is received, after passing through the lithium-ion battery, by the ultrasonic receiver. The amplitude of the received resonance frequency ultrasonic signal is measured and compared against a known baseline amplitude associated with the lithium-ion battery to calculate a percentage decrease from the known baseline amplitude. The percentage decrease is output to the user. The percentage decrease corresponds to the degree of lithium plating in the lithium-ion battery and represents a quantifiable measure of the lithium plating in the lithium-ion battery.

These and other features of the present subject matter will become readily apparent upon further review of the following specification.

### BRIEF DESCRIPTION OF DRAWINGS

FIG. 1 is a block diagram illustrating system components for performing the method of measuring lithium plating in lithium-ion batteries.

FIG. 2 illustrates ultrasonic reflection and transmission in a wave model of a multi-layer lithium-ion battery.

FIG. 3A is a graph comparing the recursive stiffness matrix (RSM) against the cutoff signal for amplitude of the reflection coefficient plotted as a function of ultrasonic frequency range in the wave model of the multi-layer lithium-ion battery.

FIG. 3B is a graph comparing the recursive stiffness matrix (RSM) against the cutoff signal for amplitude of the transmission coefficient plotted as a function of ultrasonic frequency range in the wave model of the multi-layer lithium-ion battery.

FIG. 4A illustrates typical time-domain transmission signals at four differing ultrasonic frequencies.

FIG. 4B illustrates frequency spectra respectively corresponding to the time-domain transmission signals of FIG. 4A.

FIG. 5A is a graph showing measured voltage/current vs. cycling time in room temperature cycling of a battery charging at 0.25 C.

FIG. 5B is a graph showing measured 2.25/5 MHz ultrasonic spectral amplitude vs. cycling time in room temperature cycling of a battery charging at 0.25 C.

FIG. 5C is a graph showing measured voltage/current vs. cycling time in room temperature cycling of a battery charging at 0.5 C.

FIG. 5D is a graph showing 2.25/5 MHz ultrasonic spectral amplitude vs. cycling time in room temperature cycling of battery charging at 0.5 C.

FIG. 6 illustrates wave attenuation caused by scattering in an ultrasonic wave propagation model.

FIG. 7 is a graph illustrating amplitude attenuation caused by porosity change resulting from Li intercalation.

FIG. 8A is a graph showing measured voltage/current vs. cycling time at 5° C. during cycling of a battery charging at 0.25 C.

FIG. 8B is a graph showing measured 2.25/5 MHz ultrasonic spectral amplitude vs. cycling time at 5° C. during cycling of a battery charging at 0.25 C.

FIG. 8C is a graph showing measured voltage/current vs. cycling time at 5° C. during cycling of a battery charging at 0.5 C.

FIG. 8D is a graph showing 2.25/5 MHz ultrasonic spectral amplitude vs. cycling time at 5° C. during cycling of battery charging at 0.5 C.

FIG. 9A is a graph showing voltage/current vs. cycling time at 5° C. and 25° C. for 0.25 C.

FIG. 9B is a graph showing the first order derivative of voltage/current vs. cycling time at 5° C. and 25° C. for traditional ultrasonic spectral amplitude for 0.25 C.

FIG. 9C is a graph showing the first order derivative of voltage/current vs. cycling time at 5° C. and 25° C. for resonance ultrasonic spectral amplitude for 0.25 C.

FIG. 9D is a graph showing voltage/current vs. cycling time at 5° C. and 25° C. for 0.5 C.

FIG. 9E is a graph showing the first order derivative of voltage/current vs. cycling time at 5° C. and 25° C. for traditional ultrasonic spectral amplitude for 0.5 C.

FIG. 9F is a graph showing the first order derivative of voltage/current vs. cycling time at 5° C. and 25° C. for resonance ultrasonic spectral amplitude for 0.5 C.

FIG. 10A is a graph showing voltage/2.25/5 MHz spectral amplitude vs. cycling time during Li plating detection with varying frequencies during fast charging (1 C) at room temperature.

FIG. 10B is a graph showing voltage vs. capacity during Li plating detection with varying frequencies during fast charging (1 C) at room temperature.

Similar reference characters denote corresponding features consistently throughout the attached drawings.

### DETAILED DESCRIPTION

Lithium-ion batteries (LIBs) have typical multi-layer and fluid-filled porous structures, necessitating a sophisticated model for wave propagation analysis. An intact battery wave model must be built to analyze the bandgap effect caused by the quasi-periodic structure. The recursive stiffness matrix (RSM) method, which is often used to simulate waves in a layered structure, is adopted in the following to predict the transmission spectrum. Continuity of displacement and stress at layers are assumed, and the stiffness matrices of adjacent layers can be amalgamated. By utilizing the combined matrix along with the stiffness matrix of the subsequent layer, the method is applied iteratively to obtain the global stiffness matrix, which relates stresses to displacements across the top and bottom surfaces of the structure.

Considering that the electrolyte within the battery exhibits fluidic behavior and the electrodes consist of saturated porous materials, the propagation of shear waves is significantly constrained under normal incidence. Thus, only longitudinal wave propagation must be considered in the battery wave model. The longitudinal modulus within the stiffness matrix is used to obtain acoustic impedance, which gives the global effective modulus. The effective impedance of the combination of layers N and N+1 can be expressed as follows:

$${Z}_{N}^{eff} = {Z}_{N} \frac{{Z}_{N + 1} cos ( {k}_{N} {d}_{N} ) + {iZ}_{N} sin ( {k}_{N} {d}_{N} )}{{iZ}_{N + 1} sin ( {k}_{N} {d}_{N} ) + {Z}_{N} cos ( {k}_{N} {d}_{N} )} , \qquad ( 1 )$$

where k_{N} represents the wavenumber, and d_{N} refers to the layer thickness of layer N. This calculation can be further extended, leading to the determination of the effective impedance of layer n when combined with all of its underlying layers:

$${Z}_{n}^{eff} = {Z}_{n} \frac{{Z}_{n + 1}^{eff} cos ( {k}_{N} {d}_{N} ) + {iZ}_{n} sin ( {k}_{N} {d}_{N} )}{{iZ}_{n + 1}^{eff} sin ( {k}_{N} {d}_{N} ) + {Z}_{N} cos ( {k}_{N} {d}_{N} )} . \qquad ( 2 )$$

When combined with the acoustic impedance of the initial layer, the reflection and transmission coefficients are expressed as follows:

$$R = \frac{{Z}_{1} - {Z}_{2}^{eff}}{{Z}_{1} + {Z}_{2}^{eff}} , T = \frac{2 {Z}_{2}^{eff}}{{Z}_{1} + {Z}_{2}^{eff}} . \qquad ( 3 )$$

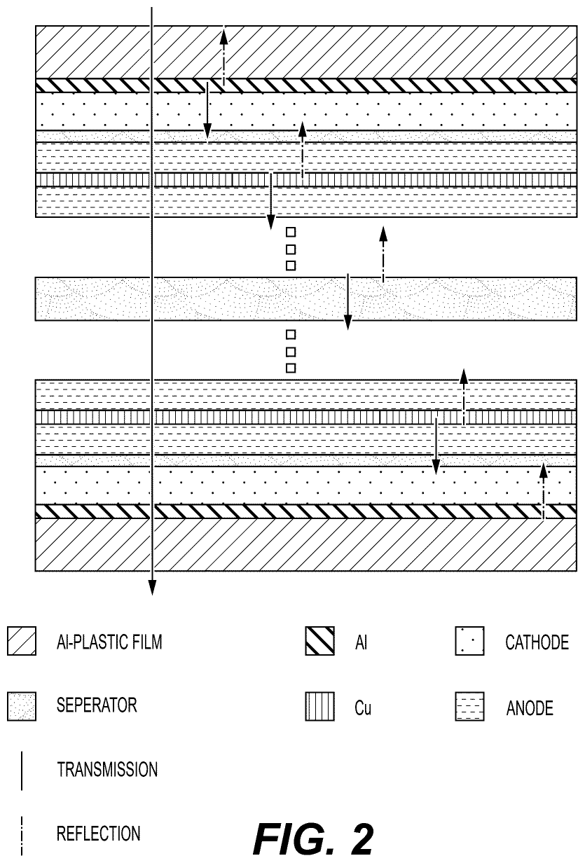

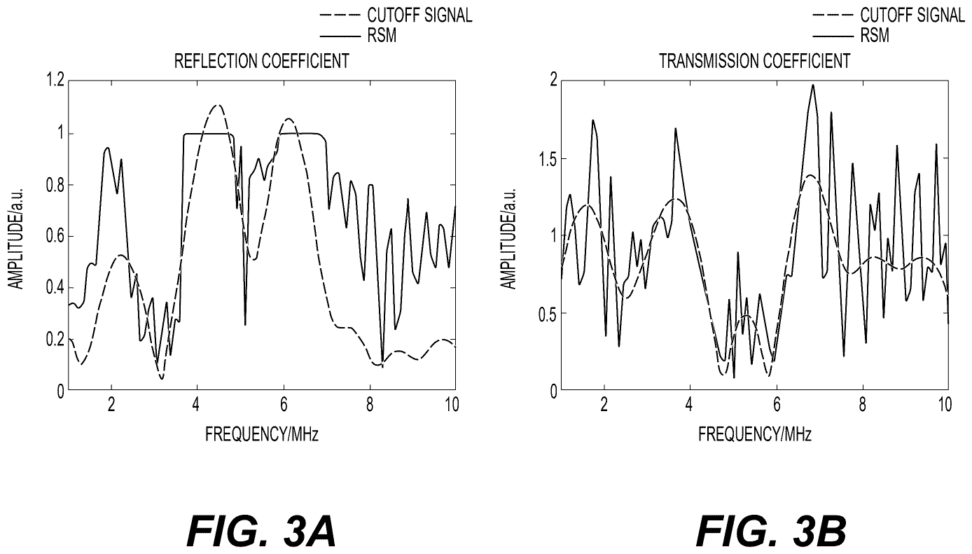

FIG. 2 shows the schematic representation of the battery model, obtained from a model NCM-575166 LIB, manufactured by Hunan Lifun of China, which was used in experiments. The model includes 76 layers of battery components, including an Al-plastic film casing. The mechanical properties of each layer were estimated using the Slurry model and Biot's theory. The resulting reflection and transmission coefficient spectra are shown in FIGS. 3A and 3B, revealing a bandgap pattern characterized by deep valleys and peaks across the entire spectrum. This phenomenon can be attributed to the multiple reflections occurring among layers with contrasting acoustic impedance. In practical scenarios, the high attenuation caused by the electrolyte and porous bi-phase electrodes tends to obscure these multiple reflections, especially for later arrivals. Thus, considering the attenuation observed in the measurements, the reflection and transmission signals are truncated up to 2 μs to match the experimental condition, after which the frequency spectrum of the truncated signal is normalized relative to the incident wave.

The normalization process results in relatively smooth and more realistic reflection and transmission spectra. As highlighted by the cutoff signal lines in FIGS. 3A and 3B, a noticeable in-phase resonant peak is evident in both the reflection and transmission spectra, occurring at approximately 4 MHz. The wave propagates backward, giving rise to the resonant reflection and also advancing forward, forming a resonant transmission wave. This characteristic enables leveraging of the in-phase resonance in the through-transmission mode, as the prominent top reflection from the Al-plastic film casing tends to mask subsequent signals from deeper layers, and the transmission also experiences less attenuation. It is noted that the resonant frequency in transmission (i.e., 3.8 MHz) is different from that in reflection (i.e., 4.2 MHz), primarily due to distinct phase changes when the wave interacts within layers of non-uniform thickness during transmission and reflection.

Another noteworthy feature observed in the transmission coefficient spectrum is a valley situated around 2.25 MHz, which aligns with the frequency commonly employed in the majority of ultrasonic detection research in literature. The 2.25 MHz signal exhibits sensitivity to variations in properties induced by the change of state-of-charge (SOC) and other defects. However, it is noted that the wavelength at 2.25 MHz is relatively large compared to the electrode scale, potentially causing the wave to overlook certain small scale defects, such as mild Li dendrite. Consequently, in the experimental setup, four distinct frequencies (1 MHz, 2.25 MHz, 5 MHz, 7.5 MHz) were utilized for comparison of their responses from LIBs, covering the complete band from 0.5-10 MHz. The wavelength spans from larger to smaller than the scale of electrodes, and the choice of frequency can lead to different phenomena arising from variations in wavelength and bandgap effects.

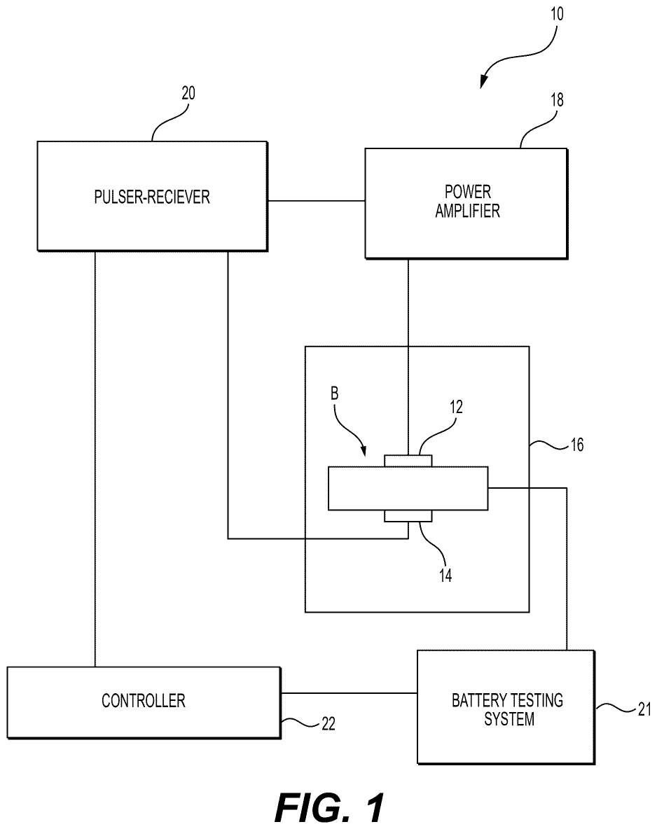

The experimental setup is illustrated in FIG. 1. Commercial pouch cells (model NCM-575166 LIB, manufactured by Hunan Lifun of China) were utilized in the experiments. These cells were placed within an incubator 16 with controlled temperatures and were subject to a constant current constant voltage (CCCV) charging and constant current (CC) discharging protocol by a battery testing system 21. Initially, the temperature in the incubator 16 was set to be 25° C. as the room temperature. The pouch cells B were first discharged to the 0% SOC at the discharging rate of 0.1 C before experiments and then underwent standard cycling procedures between 3.0 V and 4.2 V for five complete cycles. Subsequently, the temperature was reduced to 5° C., and a one-hour waiting period was set to ensure that the overall battery temperature stabilized at 5° C. Following this temperature stabilization period, the same charging rate employed during the previous room temperature cycling process was applied for charging at the low temperature and Li plating was generated. Two sets of controlled experiments were conducted to assess the impact of cycling rates on battery performance and Li plating by keeping the cycling rate at 0.5 C and 0.25 C. This allowed for assessment of the present ultrasonic spectroscopic method for monitoring the battery behavior and detecting Li plating under different cycling parameters.

Two thin ceramic piezoelectric transducer (PZT) sheets 12, 14 were mounted facing each other on the top and bottom surfaces of the battery B. The PZT sheets were securely bonded with the battery B to ensure a tight connection. Throughout the battery cycling process, one of the PZTs 12, 14 was actively controlled to excite the incident signal, while the other PZT received the transmitted signals through a pulser-receiver 20. To amplify the signal, a power amplifier 18 was employed, providing a gain of 35 dB. The excitation signals were continuously generated from low to high frequencies for the same PZT (i.e., 1 MHz, 2.25 MHz, 5 MHz, 7.5 MHz).

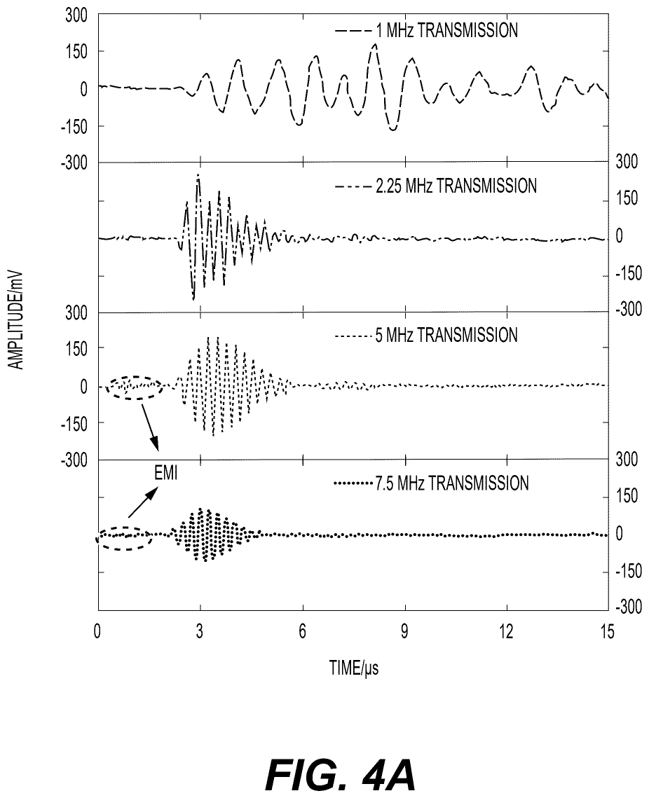

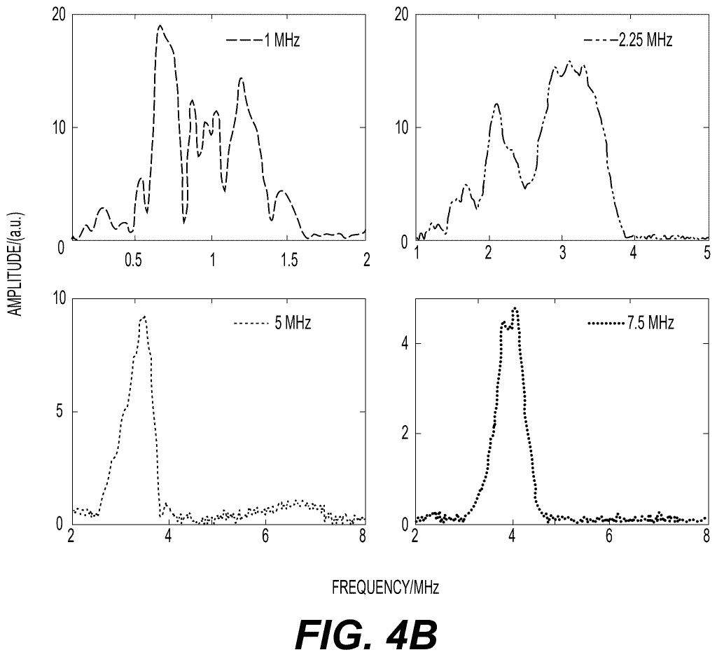

FIGS. 4A and 4B show the typical time-domain transmission signals alongside their corresponding frequency spectra associated with distinct center frequencies. To minimize the impact of noise, the time-domain signals were filtered using a Chebyshev filter with a bandpass ranging from 50 kHz to 10 MHz. All four transmission signals with different center frequencies arrived approximately at the same time. However, some minor noise was observed when the frequencies exceeded 5 MHz, which is attributed to electromagnetic interference (EMI). Nonetheless, these noise components were ahead of the transmission signals and can be effectively windowed.

As is well known, useful information, such as time-of-flight (ToF) can be extracted from signals for assessing the battery conditions. The reliability and sensitivity are significantly dependent on the method employed for calculating the ToF (e.g., peak envelop). It is influenced by the complexity of the waveform and is sensitive to noise in practical applications. As shown in FIGS. 4A and 4B, the analysis of time-domain signals can be challenging due to the presence of multiple wave packets and EMI noise. Thus, during battery operation, relying solely on time-domain signals for battery assessment overlooks the significant impact of frequency domain characteristics. In the following, the focus is on analyzing the frequency dependence and investigating the relationship with battery behavior.

The incident wave at 1 MHz has a wavelength of almost the same scale as the thickness of the battery (about 3 mm). This limits the ability to detect internal changes within the cell, and the signal exhibits oscillations due to multiple reflections from the surfaces of the battery. Consequently, the corresponding frequency spectrum is complicated due to these oscillations. The waveform of the 2.25 MHz transmission signal is composed of several wave packets. These are a mixture of interlayer and surface reflections. Notably, an observable spectrum valley, consistent with the theoretical prediction, is presented in its spectrum at approximately 2.5 MHz. In contrast, the 5 MHz transmission signal exhibits a characteristic in-phase resonance pattern. Its overall waveform includes one large wave packet with a long duration, and its spectrum features include a clear sharp peak with energy concentrated around the resonance frequency (i.e., approximately at 3.8 MHz). The 7.5 MHz signal also displays a typical in-phase resonance pattern, although a slight deviation in the predominant frequency from that of the 5 MHz signal is observed. This discrepancy is ascribed to the amplitude-frequency response of the sensor.

The analysis of frequency spectra reveals that the 1 MHz signal is characterized by a complex pattern due to multiple reflections, complicating the identification of its primary frequency. The 7.5 MHz signal introduces more significant attenuation and a lower signal-to-noise ratio (SNR), presenting challenges for signal analysis. Thus, the following analysis predominantly concentrates on the frequencies of 2.25 MHz and 5 MHz. Among the two frequencies, 2.25 MHz has been commonly utilized previously, whereas 5 MHz corresponds to the in-phase resonance frequency, which has been rarely exploited.

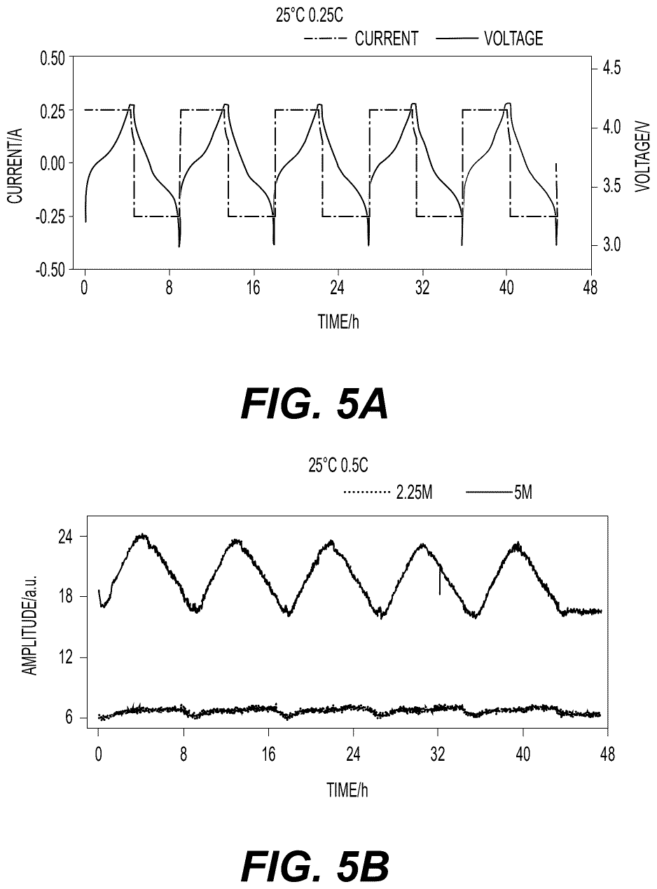

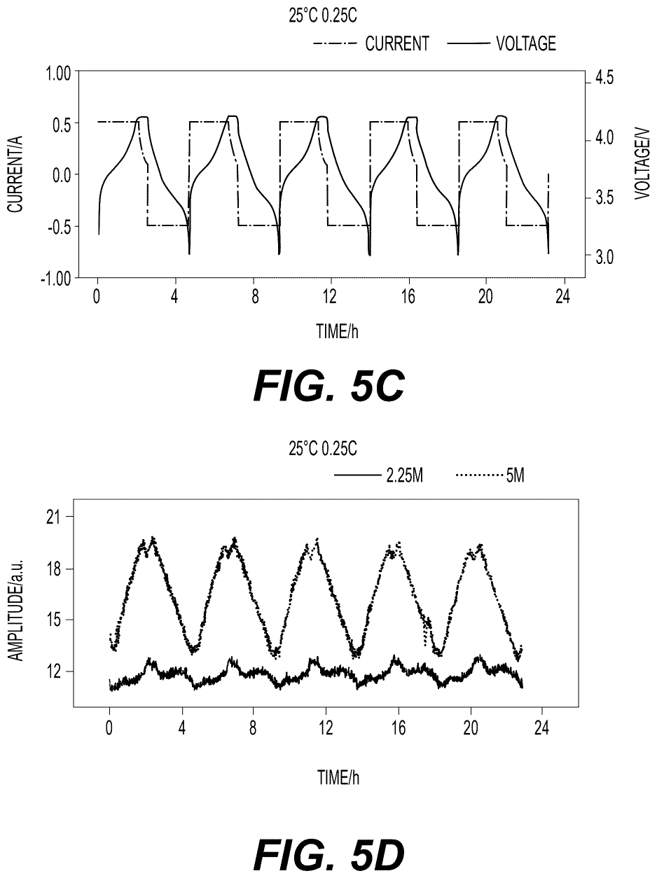

Ultrasonic experiments were conducted during battery cycles at various charge/discharge rates under the room temperature conditions, accompanied by current-voltage measurements. The results of these experiments are shown in FIGS. 5A-5D. The experiments were conducted to evaluate the impacts from SOCs on the ultrasonic measurements for an intact battery when no Li plating exists. The effects from SOCs need to be reduced largely in order to reliably detect and evaluate Li plating. The ultrasonic transmission amplitudes are extracted as the amplitudes of dominant frequency components in the spectra for 2.25 MHz and 5 MHz incident signals. It was observed that, during charging, the amplitude of the ultrasonic signals increases, while during discharging it decreases. This trend is noticeable in both frequencies, with the resonance frequency (e.g., at around 3.8 MHz) signal displaying much higher sensitivity. The amplitude changes by approximately 47.6% from SOC=0 to SOC=1, while for 2.25 MHz it only changes by 15.5%. Additionally, the amplitude change along with SOC at the resonance frequency shows a well-defined linear relationship compared with that at 2.25 MHz. As seen in FIGS. 5A-5D, the amplitude changes of the resonant frequency at 0.25 C and 0.5 C charging rates are approximately 43.8% and 47.6%, respectively, while the amplitude changes at 2.25 MHz are about 18.5% and 15.5%, respectively. Therefore, although the absolute values of ultrasonic signal amplitudes can be affected by sensors and bonding conditions, the relative change of the amplitude is stable for different charging rates, and it accurately reflects the variation in the SOC of the battery.

With regard to higher cycling rates (0.5 C), towards the end of the CC charging phase, it was further observed that a subtle decrease in the amplitude of the ultrasonic signal is detectable, followed by an increase during the subsequent CV charging phase. This phenomenon is ascribed to the conditions prevalent during high-current charging, where some lithium ions may not fully intercalate and, instead, undergo deposition as the SOC approaches 100%. Subsequently, in the CV phase, these deposited Li re-intercalate into the anode owing to the elevated anode potential. A comprehensive analysis of this phenomenon is provided below.

A quantitative analysis to explain the change in the transmission amplitude during charge/discharge cycles for an intact battery is provided. One possible reason for the linear change of amplitude with SOC is that during the charging phase, lithium ions deintercalate from the cathodes and intercalate into the anodes, inducing alterations in the overall porosity of the electrodes and the battery. Porosity stands as one of the primary factors influencing the amplitude attenuation of ultrasonic waves in porous materials. According to Biot's theory, the relationship between the attenuation coefficient, porosity, and frequency can be formulated as follows:

$$\frac{{L}_{C}}{{x}_{I}} = \frac{1}{2} \vert {ξ}_{1} {ξ}_{2} \vert \frac{{σ}_{11} {σ}_{22} - {σ}_{12}^{2}}{{γ}_{12} + {γ}_{22}} {( \frac{f}{{f}_{c}} )}^{2} , \qquad ( 4 )$$

where

$$\frac{1}{{x}_{I}}$$

is the attenuation coefficient, and f is the frequency of the propagation ultrasonic waves.

$${L}_{C} = \frac{{V}_{c}}{2 π {f}_{c}}$$

is the reference length,

$${V}_{c} = \sqrt{\frac{H}{ρ}}$$

is the reference velocity, and

$${f}_{c} = \frac{b}{2 π ρ ( {γ}_{12} + {γ}_{22} )}$$

is the reference frequency. Approximate formulas may be obtained by expanding the expression of equation (4) and keeping low-order terms. Previous research in the wave community has established the empirical relationship between the transmission amplitude of ultrasonic waves and porosity at the low-frequency range (i.e., when wavelength>>pore size):

$$\frac{1}{{x}_{I}} = ( p β + q C - m ) {( \frac{f}{{f}_{c}} )}^{2} \qquad ( 5 )$$

$${A}_{Transmission} = {A}_{Incident} {e}^{- \frac{d}{{x}_{I}}} ,$$

where β is porosity, C is solid content and p, q, and m are positive constant empirical parameters related to the mechanical properties and geometry of the porous material; the coefficients are usually estimated from experimental measurements. A is the amplitude of the ultrasonic signals, and d is the propagation length. This result has been validated by several experiment results.

With regard to calculating the attenuation coefficient using Biot's theory in the above, for a liquid-saturated porous material, ξ₁, ξ₂ are two constants related to the wavenumbers of two kinds of longitudinal waves in porous material. The mass of solid per unit volume ρ₁, the mass of fluid per unit volume ρ₂, and the mean density p are expressed by the following equation:

$${ρ}_{1} = ( 1 - β ) {ρ}_{s} , {ρ}_{2} = β {ρ}_{f} , ρ = {ρ}_{1} + {ρ}_{2} \qquad ( 6 )$$

where β is the porosity, and ρ^{f} and ρₛ are the densities of fluid and solid, respectively. The mass coefficients ρ₁₁ and ρ₂₂ as well as the coupling coefficient ρ₁₂ are formulated as functions of the tortuosity a,

$${ρ}_{11} = {ρ}_{1} - {ρ}_{12} , {ρ}_{22} = {ρ}_{2} - {ρ}_{12} , {ρ}_{12} = - ( α - 1 ) β {ρ}_{f} . \qquad ( 7 )$$

The effective porosity β_{eff} is determined as a function of the bulk modulus of the fluid K_{f}, solid Kₛ and porous drained matrix K_{b}:

$${β}_{eff} = β + \frac{{K}_{f}}{{K}_{s}} ( 1 - β - \frac{{K}_{b}}{{K}_{s}} ) . \qquad ( 8 )$$

The characteristic frequency includes the coefficient b, which is dependent on the dynamic viscosity μ of the fluid, the porosity β and Darcy's coefficient of permeability κ given as:

$$b = μ \frac{{β}^{2}}{κ} . \qquad ( 9 )$$

The Biot's parameters are established through equations involving the shear modulus Nₙ of the drained matrix:

$$A = {K}_{b} - 2 \frac{{N}_{n}}{3} + \frac{{K}_{f}}{{β}_{eff}} {( 1 - β - \frac{{K}_{b}}{{K}_{s}} )}^{2} \qquad ( 10 )$$

$$P = A + 2 {N}_{n} , Q = \frac{β {K}_{f}}{{β}_{eff}} ( 1 - β - \frac{{K}_{b}}{{K}_{s}} ) , R = \frac{{β}^{2}}{{β}_{eff}} {K}_{f}$$

$$H = P + R + 2 Q ,$$

where σ₁₁, σ₂₂, σ₁₂, γ₁₂, γ₂₂ are parameters associated with the porosity of the porous material, as well as the densities and mechanical properties of both the solid matrix and fluid, which can be determined based on Biot's parameters A, P, Q, R, and H:

$${γ}_{11} = \frac{{ρ}_{11}}{ρ} , {γ}_{22} = \frac{{ρ}_{22}}{ρ} , {γ}_{12} = \frac{{ρ}_{12}}{ρ} \qquad ( 11 )$$

$${σ}_{11} = \frac{P}{H} , {σ}_{22} = \frac{R}{H} , {σ}_{12} = \frac{Q}{H} .$$

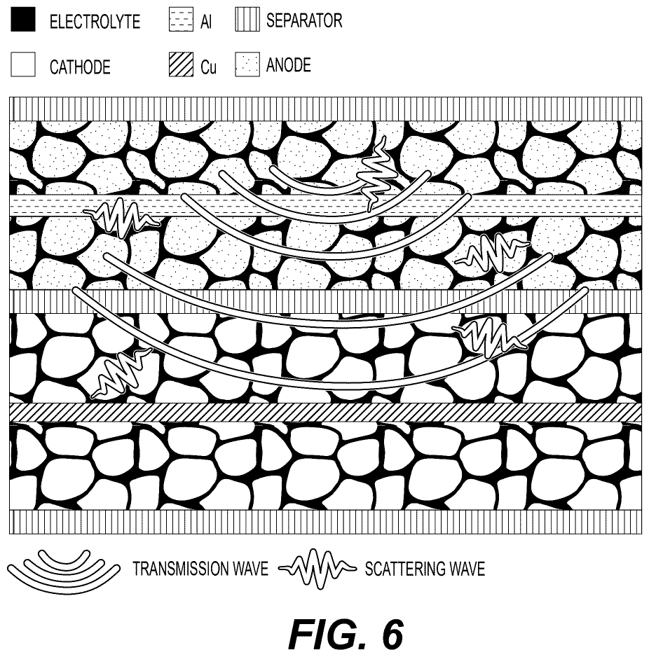

As shown in FIG. 6, the transmission of ultrasonic waves through the porous structure of electrodes experiences significant scattering. It is primarily attributed to the impedance mismatch at the solid-liquid interface coupled with the frictional forces exerted by the viscosity of the electrolyte. These factors are highly correlated with the porosity of the electrodes, which is denoted by β in equation (5). A nearly linear reduction in electrode porosity with increasing SOC has been found. Based on this knowledge, the present method incorporates empirical parameters from mechanical models reported in the literature to calculate the ultrasonic attenuation coefficient in LIBs. The electrode porosity is calculated by the electrode information provided for the particular LIB. As noted above, in experiments, commercial pouch cells (model NCM-575166 LIB, manufactured by Hunan Lifun of China) were used. The parameters for these cells are given below in Table 1:

TABLE 1
Commercial LIB Electrode Information
for Hunan Lifun Model NCM-575166 LIB

| | | |
|---|---|---|
| Cathode | Material | NCM532 |
| | Loading | 97.5% |
| | Press Density (g/cc) | 3.3 |
| | Coating Weight (mg/cm²) | 17.03 |
| | Coating Thickness (μm) | 115 |
| | Current Collector | 12 |
| | Thickness (μm) | |
| Anode | Material | AG |
| | Loading | 94.8 |
| | Press Density (g/cc) | 1.5 |
| | Coating Weight (mg/cm²) | 9.95 |
| | Coating Thickness (μm) | 141 |
| | Current Collector | 8 |
| | Thickness (μm) | |

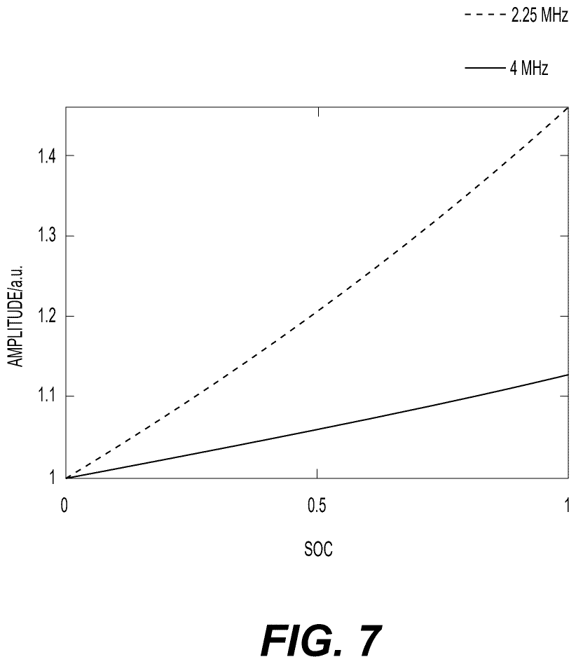

Changes in the battery porosity during cycling are mainly caused by the volume changes in the graphite, which constitutes about 90% of the anode material. At SOC=0, the anode porosity of approximately 30% from the electrode data of Table 1 is calculated. Then, during charging, the volume of the graphite expands by approximately 10% at SOC=1, resulting in an overall porosity change of approximately 6% (i.e., reducing to approximately 24%). As shown in FIG. 7, the amplitude of ultrasonic waves and battery SOC is estimated with equation (5), revealing that the transmission amplitude increases nearly linearly with SOC. Notably, the amplitude change at 4 MHz is significantly more distinct than at 2.25 MHz, with the ratio of amplitude changes at these two frequencies being approximately proportional to the square of their frequencies. As shown in FIG. 7, the amplitude changes of the resonant frequency are approximately 45.6%, while the amplitude changes at 2.25 MHz are about 12.6%. The theoretical predictions reasonably agree well with the experiment results.

In order to yield low-temperature charging results, a battery charging process was conducted in a low-temperature condition to introduce Li plating. A low temperature is known to impact the performance of a battery due to several factors, including reduced ionic conductivity, limited solid diffusivity of lithium ions within electrodes, and sluggish charge-transfer rates. Lithium ions are prone to aggregating at the graphite particle-electrolyte interface to form Li plating, instead of being intercalated into the anode as expected. Low-temperature-induced Li plating is a serious safety concern for LIBs.

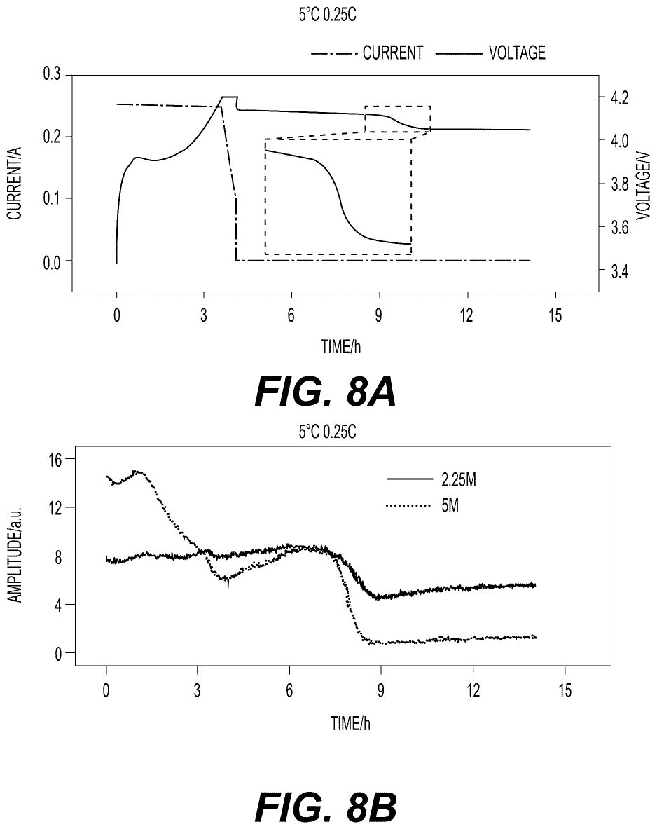

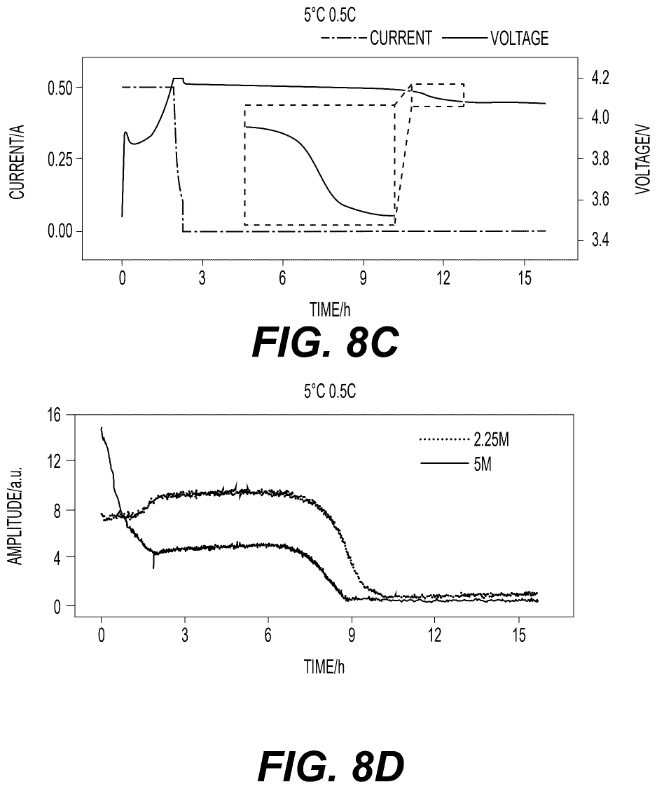

In the experiments, the battery was charged for one period at 5° C., with the same cycling rate of CCCV charging under room temperature conditions. Li plating occurs and grows during the charging process under this low temperature. Then, the battery underwent a relaxation period, during which its open-circuit voltage was recorded. Within this post-charge relaxation phase, a portion of the plated lithium underwent reversal and intercalation into the anode due to the solid phase diffusion of lithium ions in the electrode. The remaining, or irreversible plated lithium, might react with the electrolyte or become electrically disconnected from the electrode, resulting in a pool of inactive metallic lithium. As shown in FIGS. 8A and 8C, the battery voltage experiences an obvious drop between the 8th-10th hours during the relaxation process, with the preceding portion representing the plateau resulting from the re-intercalation of deposited lithium. It is suggested that the length of this plateau can serve as a metric to evaluate the amount of deposited Li metal. Notably, the battery charged at 0.5 C exhibits an extended plateau compared to the one charged at 0.25 C, indicating a more significant amount of generated Li plating. This observation aligns with the intuitive expectation that a higher charging rate will induce more Li plating.

The real-time ultrasonic spectroscopy monitoring results are shown in FIGS. 8B and 8D. The amplitude of the dominant frequency components at 2.25 MHz shows a similar trend as the room temperature cycling experiment results. It exhibits an increase during the charging phase and maintains a relatively stable amplitude after charging. Subsequently, just before the voltage drop caused by Li plating (when the Li plating-induced plateau is about to conclude) there is a sudden drop at around the 8th hour in the amplitude of the ultrasonic signal. This drop may be attributed to gas generation resulting from the reaction of some lithium with the electrolyte, physically blocking the propagation of the ultrasonic signal.

In contrast, the resonance signal amplitude demonstrated distinct behavior in the low-temperature charging experiment. During the 5° C.-0.25 C charging period, the amplitude of the resonance frequency first increased from around 14 to 15.5 (a.u.), as shown in FIG. 8B, during the first one hour with the progression of charging. Then it began to exhibit a dramatic and abnormal decrease to about 5 (a.u.) until the end of the charging process, indicating a large amount of Li plating in the battery. It is noted that the amplitude decrease shows an opposite trend compared with the Li plating-free case for an intact battery under room temperature during the same charging process, as shown in FIGS. 5A-5D. The significant attenuation observed at the resonance frequency is qualitatively explained as follows: At the low-temperature condition, Li plating appears ununiformly at most of the battery anode layers, leading to varying anode porosities and Li layer thicknesses. This variation across the cell disrupts the periodicity of the battery structure and weakens the resonance effect, resulting in a decrease in the amplitude of resonance frequency. Additionally, the deposited Li layer, with its typical rough morphology and structure, strongly attenuates specific frequencies of ultrasonic waves. This phenomenon is commonly observed in fibrous composite materials and sound-absorbing structures and is often exploited to absorb acoustic waves within certain bandwidths of frequencies. This attenuation increases rapidly with increasing frequency, and there are usually some bandgap effects, which cause the amplitude change of the resonant frequency larger than that of 2.25 MHz. This phenomenon can be utilized to significantly increase the reliability and robustness of detecting mild Li plating. The reverse change emerges shortly after the onset of low-temperature charging, offering a high sensitivity in identifying very early-stage Li plating. More importantly, because it opposes the amplitude change trend caused by SOC variations observed during room temperature cycling, the Li plating can be effectively decoupled from SOC influences using this reverse change.

Subsequently, during the resting period, the ultrasonic amplitude slightly rebounds due to the slow re-intercalation of deposited lithium into the graphite anode, reducing the Li layer thickness, and decreasing the attenuation effect. The gradual rise in signal amplitude during the rest period, caused by the lithium re-intercalation process, further validates the correlation between this reverse change phenomenon and the quantity of deposited lithium in the battery. As the Li plating-induced plateau approaches its end, the amplitude of the resonance signal undergoes a sudden decrease. The decrease is caused by gas generation, blocking the propagation of ultrasonic waves at different frequencies.

For the 5° C.-0.5 C charging case, the spectral amplitude of the resonant frequency exhibits a downward trend from the beginning until the end of the charging process. The magnitude of the decrease is slightly greater than that at 0.25° C. This indicates that at higher charging rates under the same low temperature, the Li plating phenomenon occurs earlier and to a more severe extent than at lower rates. It can be observed that a higher charging rate leading to a greater amount of Li plating results in a more significant decrease in signal amplitude, reaching below 5, and a slower Li re-intercalation. This finding aligns with previous studies. During the resting period, the signal shows a similar trend at 0.25 C, slowly rising and then suddenly declining before the amplitude plateau ends. Moreover, the amplitudes of both frequencies drop close to 0, indicating more severe gas generation and implying more severe Li plating compared to the lower rate charging.

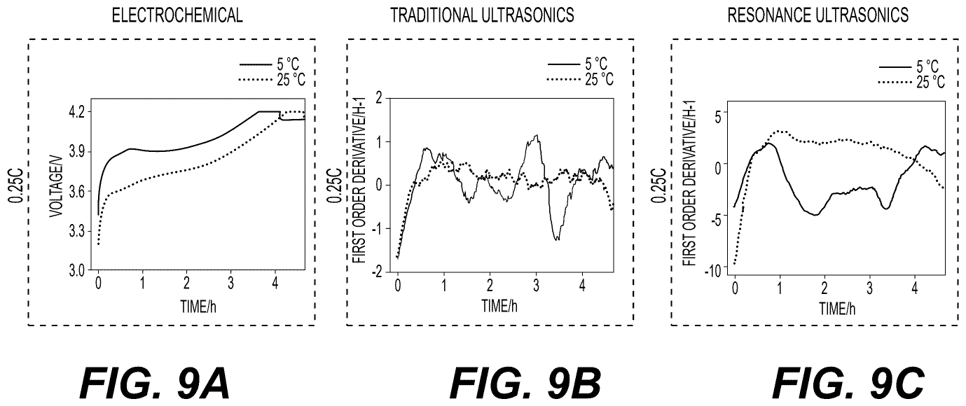

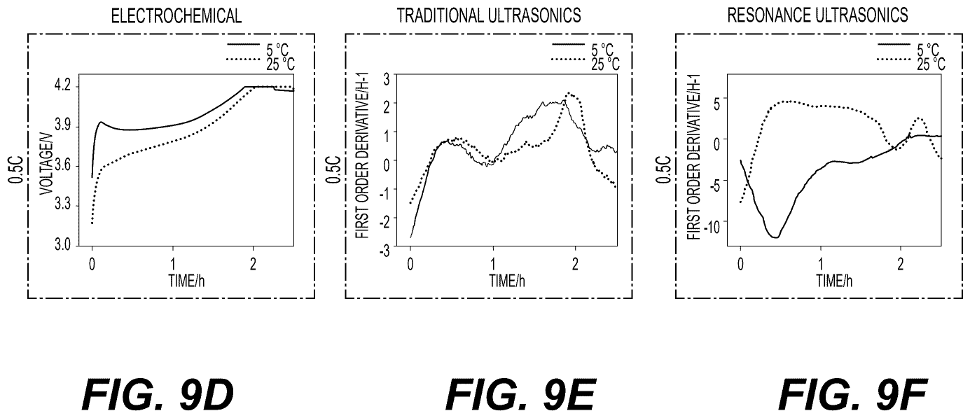

To further demonstrate the sensitivity and reliability of ultrasonic spectroscopy for Li plating detection under different temperature conditions and at different charging/discharging rates, the electrochemical and ultrasonic data corresponding to the charging process at room temperature and low temperature within the same period were extracted. As shown in FIGS. 9A and 9D, when the low-temperature CC charging begins, the battery voltage significantly increases, experiences a slight drop, and gradually rises again until the voltage reaches the preset value of 4.2V to initiate CV charging. The CC stage is slightly shorter at the low temperature compared to room temperature. In FIGS. 9B, 9C, 9E and 9F, the first-order derivative of the ultrasonic spectral amplitude with respect to time (e.g., differentiated ultrasonic amplitude) is plotted. In FIGS. 9B and 9E, the differentiated amplitude curves for the commonly used 2.25 MHz ultrasonic signal exhibit a similar trend during the low temperature and room temperature charging process and show predominantly positive values. As shown, the plotted lines mostly overlap. Distinguishing whether the battery undergoes minor Li plating during low-temperature charging based on this slight difference is not reliable for 2.25 MHz.

When examining the derivative of the resonant frequency amplitude, as depicted in FIGS. 9C and 9F, the signal-to-noise ratio (SNR) is significantly improved. The background fluctuation of the resonance ultrasonic signal is about 0.05 h⁻¹, while the derivative magnitude is about 5 h⁻¹, yielding an SNR of 40 dB compared to the 23.4 dB SNR of the traditional ultrasonic signal. Additionally, a distinctive reverse change is observed during low-temperature charging, specifically, the first-order derivative of the resonance frequency amplitude is mostly negative. This results in easy and clear differentiation between the cases with Li plating and without Li plating. As explained above, this reverse trend is attributed to the high sensitivity of the amplitude of the resonant frequency to changes in porosity and the increased susceptibility to ultrasonic attenuation effects caused by the porous lithium dendritic layer formed on the anode surface. Furthermore, it is noticeable that during 0.25 C charging, the derivative is initially positive, transitioning to negative for a long period, while during 0.5 C charging, the derivative consistently remains negative. This suggests that Li plating during the low-rate charging process occurs later than during high-rate charging. Additionally, a higher charging rate results in a larger absolute differentiated amplitude (i.e., a more pronounced decrease in signal amplitude), indicating a more significant amount of Li plating is produced. The amplitude derivative exhibits an increasing trend during the CV stage at both charging rates, signifying the mitigation of lithium plating in this phase. Moreover, during the resting phase, the derivative recovers to positive, indicating a re-intercalation of the plated lithium during the rest period. Thus, the first-order derivative of the spectral amplitude of the resonant frequency component can function as an indicative parameter for characterizing the quantity of active lithium in the battery, reflecting the severity of Li plating.

To further examine the level of Li plating induced by charging at a low temperature, the battery was disassembled in a glove box after completing the CCCV charging process at both room temperature and low temperature. The anodes showed a uniform golden color after charging at 25° C., indicating the formation of LiC₆ resulting from lithium intercalation. The separators appeared clean with no residue, suggesting that no lithium plating occurred during charging at room temperature. However, a conspicuous layer of white frost-like Li plating was evident on the anode surface during low-temperature charging at 5° C. During the disassembly process, some deposited lithium and graphite anode powders detached from specific areas, adhering to the separator. Notably, at the same low temperature, Li plating resulting from high-rate charging (0.5 C) was notably more pronounced, aligning with expectations and being consistent with the findings of ultrasonic measurements.

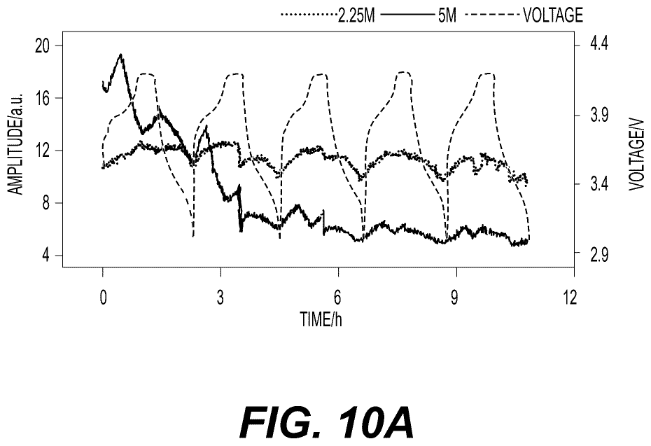

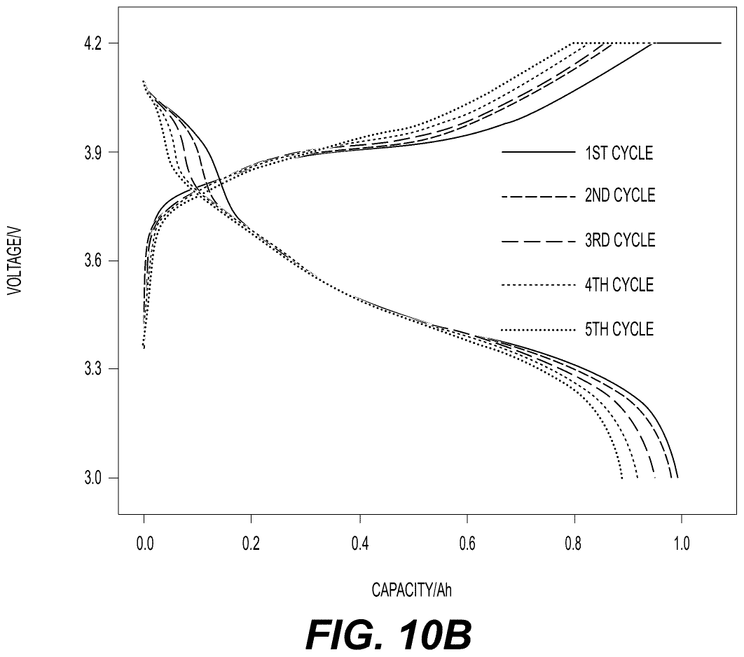

After validating the capability of ultrasonic spectroscopy to detect Li plating through control experiments under low-temperature conditions, the same method was used to monitor Li plating growth of the same pouch cell subjected to fast charging under room temperature. As illustrated in FIGS. 10A and 10B, the battery underwent 5 cycles at 25° C. with a 1 C rate, while simultaneous monitoring of changes in ultrasonic spectroscopy was conducted.

In FIG. 10A, the amplitude of the 2.25 MHz frequency component varies with SOC, demonstrating an overall stable increase and decrease trend. Conversely, the amplitude of the resonant frequency component shows a noticeable overall decrease, particularly pronounced in the first two cycles, which suggests the occurrence of Li plating during this period. This observation is supported by FIG. 10B, which shows a distinct voltage plateau during the discharge phase, confirming the presence of Li plating and re-intercalation processes. While this phenomenon slows down in the subsequent three cycles, a slight ultrasonic amplitude decrease during charging still suggests ongoing Li plating. The inconspicuous voltage plateau in the subsequent discharge may reveal that the Li deposition is not reversible; i.e., most of them either react with electrolyte to form solid electrolyte interphase (SEI) or form dead Li, which can be supported by the quickly decreased discharge capacity in these three cycles. The length of the plateau reflects the quantity of deposited Li, and it is evident that more Li plating is generated in the first two cycles compared to the subsequent three cycles, aligning with the results obtained from ultrasonic spectroscopy.

Due to the pronounced Li plating in the first two cycles, we focus on the changes in ultrasonic signals during these initial two cycles in FIG. 10A. During the CC charging stage, the amplitude initially increases with SOC, followed by a rapid decrease. Subsequently, during the CV charging stage, the amplitude rises slightly again up until the discharge phase, where it decreases. This indicates that Li plating begins shortly after the start of CC charging. During the CV stage, some lithium re-intercalates into the graphite anode due to increased anode potential. However, due to the substantial amount of Li plating, it does not fully re-intercalate, leading to a significant overall decrease in amplitude. Consequently, during the discharge phase, there is a noticeable voltage plateau. This observation aligns with the battery capacity in FIG. 10B. This phenomenon was also observed in previous experiments under room temperature at 0.5 C cycling rate, where Li plating onset was later at SOC closer to 100% during CC charging.

The above observations indicate that ultrasonic spectroscopy is highly sensitive to Li plating in LIBs. The spectral amplitude of the resonance frequency has the potential to serve as a factor for monitoring the occurrence of Li plating during battery operation. This capability can be utilized to explore optimal battery charging and discharging strategies, as well as operating temperatures.

As discussed above, in use, the lithium (Li) plating in a lithium-ion battery may be measured as a decrease in resonance frequency amplitude observed during the charging process of the lithium-ion battery. Referring again to FIG. 1, an ultrasonic transmitter 12 is attached to one side of the lithium-ion battery B and an ultrasonic receiver 14 is attached to an opposite side of the lithium-ion battery B. As a non-limiting example, each of the ultrasonic transmitter 12 and the ultrasonic receiver 14 may be a piezoelectric transducer (PZT). The lithium-ion battery B is charged and, during the electrical charging thereof, a resonance frequency ultrasonic signal is transmitted through the battery B using the ultrasonic transmitter 12, and the signal is received, after passing through the lithium-ion battery B, by the ultrasonic receiver 14. The amplitude of the received resonance frequency ultrasonic signal is measured and compared against a known baseline amplitude associated with the lithium-ion battery B to calculate a percentage decrease from the known baseline amplitude. The percentage decrease is output to the user using any suitable type of interface. As a non-limiting example, controller 22 may be a computer, personal computer, laptop computer or the like, and the percent decrease may be output to the user on a display associated therewith. The percentage decrease corresponds to the degree of lithium plating in the lithium-ion battery B and represents a quantifiable measure of the lithium plating in the lithium-ion battery B.

The resonant frequency is not universal for all lithium-ion batteries, thus the known baseline amplitude of the resonance frequency must be determined for each individual type of lithium-ion battery. The known baseline amplitude for each type of lithium-ion battery may be stored in, for example, a database stored in memory of the controller 22. For the particular type of battery B being charged and tested, the known baseline amplitude for that particular type of battery is used. The resonance frequency of each type of lithium-ion battery varies depending on factors such as cell geometry, electrode composition and internal structure. Determining the baseline resonant frequency of the battery must be performed as an initial calibration step for each battery type prior to monitoring. This ensures that subsequent resonance shifts are accurately referenced to the cell's intrinsic frequency response. The baseline received amplitude is also determined at this preliminary calibration stage.

Rather than using a fixed excitation frequency, the intrinsic resonant frequency of each specific type of battery is measured. The ultrasonic signal transmitted by ultrasonic transmitter 12 is then tuned to this resonance frequency (using controller 22 in conjunction with pulser-receiver 20 and power amplifier 18), which serves as the acoustically sensitive operating point for detecting the Li plating. During charging, Li plating alters the local acoustic impedance and stiffness, causing a measurable decrease in resonance frequency amplitude measured by ultrasonic receiver 14 (in communication with pulser-receiver 20 and controller 22).

During the charging process, Li plating leads to local changes in the mechanical impedance of the electrode-electrolyte interface and breaks the periodicity of the layer structure which, in turn, causes a measurable decrease in the resonance frequency amplitude of the transmitted ultrasonic signal. Thus, the decrease of the resonance frequency amplitude during the charging process provides a direct and quantifiable determination of Li plating occurrence. The actual indicator of Li plating is the decrease in resonance frequency amplitude observed during the charging process. To provide a quantitative diagnostic measure, the percentage decrease in resonance frequency amplitude relative to the initial (baseline) value can be used as a severity index for Li plating. For example, a decrease of a defined percentage (e.g., 5-10%) from the calibrated baseline amplitude can be interpreted as the progression of Li plating.

The battery tester 21 shown in FIG. 1 may be used to control the charging and discharging of the battery B and to record the corresponding voltage and current during cycling. During experimentation, a model CT3002A battery test system, manufactured by Landt Instruments, was used as the battery testing system 21. The battery testing system 21 is used to synchronize the electrochemical state of the cell (e.g., during charging or discharging) with the ultrasonic measurements collected by the pulser-receiver 20 and controller 22. The pulser-receiver 20 and controller 22 handle ultrasonic excitation and signal acquisition, while the battery tester 21 performs electrochemical cycling and monitoring to correlate changes in ultrasonic resonance amplitude with the actual charging state and occurrence of Li plating.

It is to be understood that the method of measuring lithium plating in lithium-ion batteries is not limited to the specific embodiments described above, but encompasses any and all embodiments within the scope of the generic language of the following claims enabled by the embodiments described herein, or otherwise shown in the drawings or described above in terms sufficient to enable one of ordinary skill in the art to make and use the claimed subject matter.

1. A method of measuring lithium plating in lithium-ion batteries, comprising:
attaching an ultrasonic transmitter to one side of a lithium-ion battery and attaching an ultrasonic receiver to an opposite side of the lithium-ion battery;
electrically charging the lithium-ion battery;
during the electrical charging of the lithium-ion battery, transmitting a resonance frequency ultrasonic signal through the lithium-ion battery using the ultrasonic transmitter and receiving the resonance frequency ultrasonic signal using the ultrasonic receiver;
measuring an amplitude of the received resonance frequency ultrasonic signal;
comparing the amplitude of the received resonance frequency ultrasonic signal against a known baseline amplitude associated with the lithium-ion battery to calculate a percentage decrease from the known baseline amplitude; and
outputting the percentage decrease to a user, wherein the percentage decrease corresponds to a degree of lithium plating in the lithium-ion battery.

2. The method of measuring lithium plating in lithium-ion batteries as recited in claim 1, wherein each of the ultrasonic transmitter and the ultrasonic receiver comprises a piezoelectric transducer.

3. The method of measuring lithium plating in lithium-ion batteries as recited in claim 1, further comprising determining a baseline resonant frequency associated with the lithium-ion battery.

4. The method of measuring lithium plating in lithium-ion batteries as recited in claim 3, wherein the determination of the baseline resonant frequency associated with the lithium-ion battery is performed prior to the attaching of the ultrasonic transmitter and the ultrasonic receiver to the lithium-ion battery.
